(19) United States
(12) Patent Application Publication
(10) Pub. No.: US 2022/0406668 A1
(43) Pub. Date: Dec. 22, 2022

(54) ELECTRONIC CHIP

(71) Applicant: STMicroelectronics (Rousset) SAS, Rousset (FR)

(72) Inventor: Francois TAILLIET, Fuveau (FR)

(73) Assignee: STMicroelectronics (Rousset) SAS, Rousset (FR)

(21) Appl. No.: 17/839,976

(22) Filed: Jun. 14, 2022

(30) Foreign Application Priority Data
Jun. 17, 2021 (FR) 2106460

(51) Int. Cl. H01L 21/66; H01L 23/58; H01L 23/00

(52) U.S. Cl. CPC H01L 22/32; H01L 23/585; H01L 23/562; H01L 23/564

(57) ABSTRACT

An electronic chip includes a seal ring whose shape is contained within a rectangle, of a width equal to a maximum width of the electronic chip and a length equal to a maximum length of the electronic chip. At least one test pad is arranged at least partially within the rectangle. The test pad is shared with at least one other adjacent electronic chip.

### PRIORITY CLAIM

This application claims the priority benefit of French Application for Patent No. 2106460, filed on Jun. 17, 2021, the content of which is hereby incorporated by reference in its entirety to the maximum extent allowable by law.

### TECHNICAL FIELD

The present disclosure relates to electronic chips in general and, more particularly, to the manufacture of such electronic chips.

### BACKGROUND

In industry, most electronic devices are manufactured in series. Generally, several copies of the same electronic device are manufactured simultaneously in and on the same plate, known as a wafer.

The number of electronic chips that can be placed on the same wafer depends on the chip dimensions and the spacing between them. This spacing is determined by taking into account different constraints such as the precision with which different manufacturing steps are performed, the technology used to separate the chips from each other or the placing of ephemeral elements on the board.

It would be desirable to be able to improve the electronic chips and their manufacturing methods, at least in part.

There is a need for microchip manufacturing methods that make it possible to manufacture more chips on a single wafer.

### SUMMARY

One embodiment addresses all or some of the drawbacks of known electronic integrated circuit chips manufacturing methods.

One embodiment addresses all or some of the drawbacks of known electronic chips. One embodiment provides for an electronic chip comprising a seal ring whose shape is contained within a rectangle of a width equal to the maximum width of said chip and of a length equal to the maximum length of said chip, and at least one test pad arranged in said rectangle, at least partially, said test pad being shared with at least one other electronic chip.

According to one embodiment, said test pad is arranged outside of said seal ring.

According to one embodiment, said seal ring has a substantially rectangular-shaped recess at the location of said test pad, said test pad being embedded in said recess.

According to one embodiment, the chip comprises at least one circuit arranged in an area of the same size as the recess and arranged against a first side of the chip opposite a second side of the chip on the side of which said recess is formed, said circuit being a circuit whose position in said chip can be modified.

According to one embodiment, said test pad is arranged on a cutting line that makes it possible to individualize said chip at the end of its manufacturing method.

According to one embodiment, said test pad is positioned next to a cutting line that makes it possible to individualize said chip at the end of its manufacturing method.

According to one embodiment, said test pad is arranged inside said seal ring, and said seal ring has the shape of said rectangle.

According to one embodiment, said test pad is shared with a group of electronic chips. According to one embodiment, said test pad is connected to said other electronic chip by a communication bus made of a non-metallic material.

According to one embodiment, said communication bus is made of polycrystalline silicon.

Another embodiment provides a method for manufacturing a group of electronic chips described above, comprising a step of individualizing the chips performed by a particle beam cutting method.

According to one embodiment, the particle beam cutting method is a plasma cutting method.

According to one embodiment, the particle beam cutting method is associated with a laser cutting method.

According to one embodiment, the electronic chips are spaced apart from each other by a minimum spacing defined by the cutting method.

According to one embodiment, the spacing of the chips is greater than or equal to 15 μm.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows a view of a wafer, from above, very schematically and in block form;

FIG. 2 shows a view of an electronic chip, from above, schematically and in block form;

FIG. 3 shows a view of a step in an electronic chip manufacturing method, from above, schematically and in block form;

FIGS. 4A and 4B show two simplified views of a step in an electronic chip manufacturing method, from above, schematically and in block form;

FIG. 5 shows a simplified view of a step in another embodiment of an electronic chip manufacturing method, from above, schematically and in block form;

FIG. 6 shows a simplified view of a step in another embodiment of an electronic chip manufacturing method, from above, schematically and in block form;

FIG. 7 shows a simplified view of a step in another embodiment of an electronic chip manufacturing method, from above, schematically and in block form;

FIG. 8 shows a simplified view of a step in another embodiment of an electronic chip manufacturing method, from above, schematically and in block form; and

FIG. 9 shows a simplified view of a step of another embodiment of an electronic chip manufacturing method, from above, schematically and in block form.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the manufacturing steps of the circuits included in an electronic chip are not described here, with the usual manufacturing steps of these circuits being compatible with the described embodiments.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

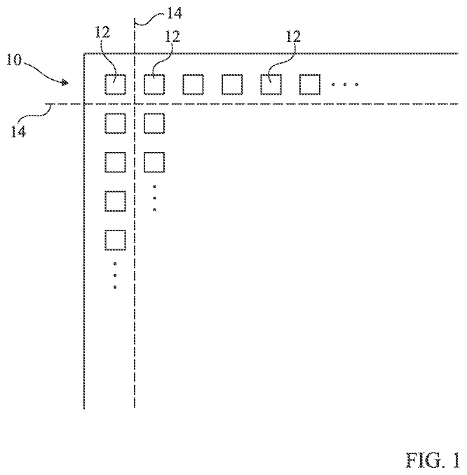

FIG. 1 is a highly schematic, block view from above of a wafer 10 in and on which electronic chips 12 are formed. Only a portion of the wafer 10 is visible in FIG. 1.

The electronic chips 12 are arranged in array form, that is, in lines and columns. The chips 12 are identical circuits manufactured in series in and on the wafer 10, for example, but, in a variant, may be different circuits but of similar size, for example, in order to be able to optimize the distribution of circuits 12 on the wafer 10.

The electronic chips 12 are all formed simultaneously on the wafer 10. Once the manufacture and assembly of circuits of the chips 12 is complete, compliance tests should be performed. These tests are performed using test pads connected to the chips, not shown in FIG. 1, and described in more detail below.

The chips 12 can then be separated, or individualized, through a singulation process so that they can be used on their own, for example, or in a more complete electronic system. To individualize the chips 12, the wafer 10 can be cut along cutting lines 14, designated as dotted lines in FIG. 1. There are various cutting methods making it possible to individualize the chips, several of which will be described below.

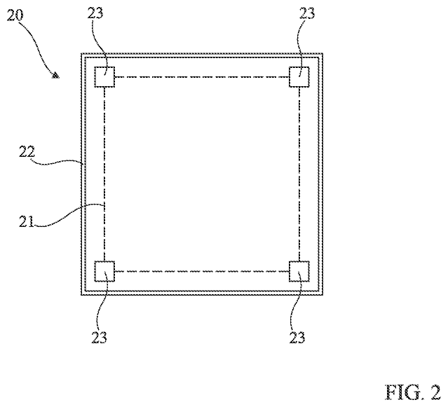

FIG. 2 schematically shows a view from above of an electronic chip 20 of the type of chips 12 described in connection with FIG. 1.

The electronic chip 20 is substantially rectangular or rectangular in shape, or substantially square or square in shape, and includes at least one functional circuit 21 formed in an area designated by dotted lines. The electronic chip 20 generally comprises a plurality of functional circuits 21 connected to each other, by conductive tracks, for example. The functional circuit 21 may or may not be protected by a housing.

The functional circuit 21 is surrounded by a seal ring 22 that defines the edge of the chip 20. In the following description, the shape of an electronic chip will be considered defined by the shape of its seal ring. The seal ring 22 may be composed of a stack of interconnecting metal layers comprising a network of vias. A metal layer of this stack may be connected to an active layer of the wafer or plate in and on which the chip 20 is formed. The active layer may be a layer of the same doping type as the wafer, for example. The seal ring 22 provides mechanical protection of the edges of the chip 20, and protection of the chip 20 from diverse contamination, such as corrosion. The seal ring 22 may further make it possible to connect to a reference potential, such as ground, of the circuit periphery of the chip 20.

The electronic chip 20 may comprise one or more connection pads 23, accessible for connecting the chip 20 to other chips, circuits, or electronic components. In FIG. 2, the electronic chip comprises four connection pads 23, each positioned in a corner of the chip 20.

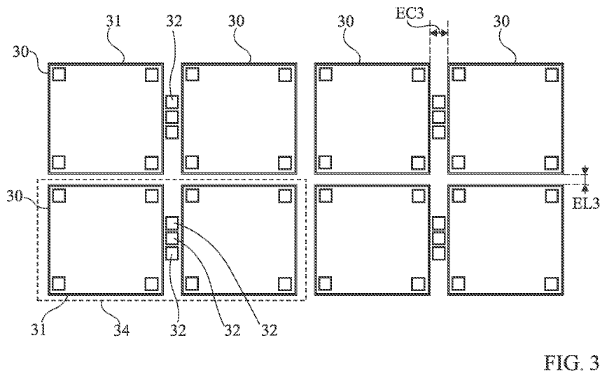

FIG. 3 is a view of an electronic chip 30 manufacturing step, from above.

The electronic chips 30 are chips of the type of chip 20 described in connection with FIG. 2. The chips 30 will not be described again in detail.

The chips 30 have all been formed on a plate (not shown), or a wafer, in the manner of the chips 12 described in connection with FIG. 1. More particularly, the chips 30 in FIG. 3 are eight in number, arranged in two lines and four columns. According to one example, the chips 30 are square in shape, with sides of between 400 and 700 μm, more specifically between 500 and 600 μm, for example.

As described in connection with FIG. 1, test pads 32, intended to perform compliance tests at the end of manufacturing the circuits of the chips 30, are arranged between the chips 30, that is, outside of the seal ring 31 defining the shape of the chip 30 (in the scribe line between adjacent chips). The test pads 32 are metal pads, made of aluminum or an aluminum alloy, for example. According to one example, the test pads 32 are substantially rectangular or even substantially square shaped pads, with sides of between 50 and 80 μm.

In the example shown in FIG. 3, compliance tests of the chips 30 are performed in a common manner for finite groups 34 of multiple chips 30, and, more particularly, of two chips 30. A group 34 may be composed of adjacent chips in the direction of a row of chips 30 or in the direction of a column of chips 30. A group 34 of two adjacent chips 30 is surrounded by dotted lines in FIG. 3, for example. According to one example, each group 34 of chips 30 is tested using three test pads 32, with said test pads 32 arranged in the spacing between the two chips 32 in the group 34, i.e., along two opposing sides of two chips 30. Furthermore, the test pads 32 are arranged on a cutting (scribe) line that makes it possible to individualize (i.e., singulate) the chips 30. Because the compliance tests are performed prior to the chip individualization step 30, the test pads 32 can be destroyed, and are destroyed, during the chip individualization step 30.

In the step shown in FIG. 3, the chips 30 are ready to be individualized, and the method used to do so is sawing. Sawing is an inexpensive cutting method, but imposes various constraints on the spacing between the chips 30.

The spacing of the chips 30 is thus constrained by the placing of the test pads 32 and by the cutting method used to individualize the chips 30. The spacing EC3 of two columns of chips 30, constrained by the placing of test pads 32, has a minimum dimension of 80 μm. The spacing EL3 of two rows of chips 30, constrained by the cutting method used, has a minimum dimension of 60 μm.

It would be desirable to be able to decrease the spacing EC3 and EL3 of the chips 30, so as to be able to position more chips 30 on the same plate or on the same wafer.

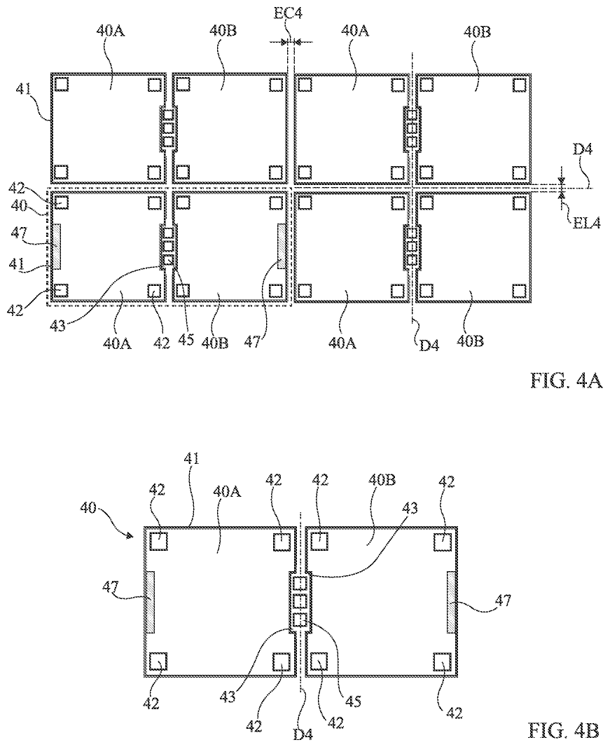

FIGS. 4A and 4B show two views from above of a step of manufacturing a plurality of finished groups 40, such as four chip groups 40, each comprising a chip 40A and a chip 40B. FIG. 4A illustrates four groups 40, and FIG. 4B illustrates a single group 40.

The chips 40A and 40B are similar to the chips 30 described in connection with FIG. 2 and the chip 20 described in connection with FIG. 2. The common elements of the chips 20, 30, 40A and 40B will not be described again in detail here. Only the differences of chips 40A and 40B in relation to the chips 20 and 30 are highlighted.

Thus, each chip 40A, 40B comprises one or more functional circuits, a portion of which is described in more detail below, surrounded by a seal ring 41 defining the shape of the chip 40A, 40B, and four connection pads 42.

In addition, each group 40 is similar to a group 34 described in connection with FIG. 3, and thus each group 40 includes two adjacent chips 40A and 40B, between which test pads 45, identical to the test pads 32 described in connection with FIG. 3, are arranged.

The number of test pads 45 comprised in the group 40 is varies, depending on the nature of the compliance tests applied to the chips 40A and 40B. According to one example embodiment, each test group 40 comprises at least one test pad 45, such as three test pads 45. According to one example, one test pad may receive an input test signal, one test pad may transmit an output test signal, and a final test pad may provide a reference potential, such as ground.

As illustrated in FIGS. 4A and 4B, the test pads 45 are positioned between the chips 40A and 40B on a cutting line D4 separating the chips 40A and 40B. The cutting line D4 is symbolized by dotted lines in FIG. 4B. According to one example, the test pads 45 are aligned on the cutting line D4, to provide a minimal footprint.

Unlike the chips 12, 20, and 30, the chips 40A and 40B are individualized by using a cutting method comprising a particle beam cutting method, accompanied or not by a laser cutting method. The particle beam and laser cutting methods impose fewer chip spacing constraints 40A and 40B as compared to the saw cutting methods. In particular, the particle beam and laser cutting methods make possible more accurate and faster cutting of a plate, or wafer, on which the chips 40A and 40B are formed. The particle beam and laser cutting methods thus make it possible to reduce the spacing of the lines EL4 of the chips 40A and 40B and the spacing of the columns EC4 of the chips 40A and 40B. According to one embodiment, the particle beam cutting method is a plasma cutting method, which makes it possible to reduce the spacings EL4 and EC4 to a minimum dimension of 15 μm. According to one example embodiment, the spacings EL4 and EC4 are of the order of 26 μm.

An example of a cutting method making it possible to individualize the chips 40A and 40B may comprise the following successive steps:
a first laser cutting method that makes it possible to cut through the test pads 45, the material of which may not be easily cut by a particle beam cutting method;
a second laser cutting method at a lower power than the first laser cutting method that makes it possible to prepare to cut the plate on and in which the chips 40A and 40B are formed; and
a plasma cutting method that makes it possible to cut through said plate.

However, placing the test pads 45 between the chips 40A and 40B of the same group 40 prevents reducing the spacing of the rows and columns of chips 40A and 40B to the permitted minimum. For this reason, according to one embodiment, the chips 40A and 40B, and thus their seal ring 41, no longer have a rectangular or substantially square shape, but have a shape contained within a rectangle or a square of a width equal to the maximum chip width and of a length equal to the maximum chip length. In addition, according to one embodiment, the shape of the chips 40A and 40B includes a recess 43 on the side near which the test pads 45 are positioned. The recess 43 conforms to the shape of the test pads 45, so as to embed a portion of the test pads 45 into the chips 40A and 40B, and to make it possible for the chips 40A and 40B to be spaced apart by a minimum spacing that depends on the cutting method used and not on the size of the test pads. According to one embodiment, the recess 43 is substantially rectangular in shape. Since the test pads 45 are positioned between the chips 40A and 40B of the same group 40, the recess 43 is not positioned on the same side on the chip 40A and on the chip 40B. In FIGS. 4A and 4B, the chip 40A is on the left in the group 40, and its recess 43 is arranged on its right side, and, conversely, the chip 40B is on the right in the group 40, and its recess 43 is arranged on its left side. According to a preferred embodiment, the recesses 43 of the chips 40A and 40B are identical in area, but the person skilled in the art could envision asymmetrical recesses 43 between the two chips 40A and 40B.

In order to optimize the space delimited by the seal ring 41 of the chips 40A and 40B, an area 47 (shaded in FIG. 4B) of the chips 40A and 40B of the same shape and surface area as the recess 43 arranged on the side opposite the recess 43 is reserved for mobile functional circuits of the chips 40A and 40B. “Mobile functional circuits” here means circuits and/or components of the chips 40A and 40B whose physical position in the chips 40A and 40B is not set by electronic, electrical and/or mechanical constraints, that is, said physical position can be modified.

One advantage of this embodiment is that it makes it possible to reduce the spacing, that is, to bring the chips 40A and 40B closer together.

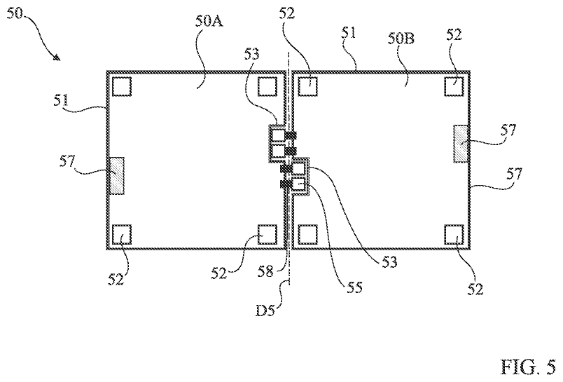

FIG. 5 is a schematic view from above of another embodiment of a finite group 50 comprising two chips 50A and 50B.

The group 50 and the chips 50A and 50B are similar to the group 40 and the chips 40A and 40B described in connection with FIGS. 4A and 4B. The elements common to the groups 40 and 50 and to the chips 40A and 40B and the chips 50A and 50B will not be described again in detail here. Only the differences between the groups 40 and 50, and the chips 40A and 40B and the chips 50A and 50B will be highlighted.

Thus, each chip 50A, 50B comprises one or more functional circuits, a portion of which is described in more detail below, surrounded by a seal ring 51 that defines the shape of the chip 50A, 50B, and four connection pads 52.

In addition, each group 50 thus includes two adjacent chips 50A and 50B, between which test pads 55 identical to the test pads 32, described in connection with FIG. 3, are arranged.

Unlike the group 40 of FIG. 4, the test pads 55 are not positioned on the cutting line D5 separating the chips 50A and 50B, but are fully embedded in the chips 50A and 50B. More particularly, each chip 50A and 50B comprises recesses 53 on the side of the test pads 55, similar to the recesses 43 described in connection with FIG. 4, except that the recesses 53 are large enough to completely embed one or more test pads 55. According to one example, in order to have chips 50A and 50B with the same surface area, the group 50 includes an even number of test pads 55, such as four test pads in FIG. 5, and a first half of the test pads 55 are recessed in the chip 50A, and a second half of the test pads 55 are recessed in the chip 50B. In addition, the test pads 55 are always positioned on top of each other so as to minimize the spacing between the chips 50A and 50B as much as possible. Thus, the recesses 53 of the chips 50A and 50B are not arranged face-to-face, but are offset from each other. According to one example, if the compliance tests of the chips 50A and 50B require only an odd number of test pads 55, such as three test pads 55, two test pads 55 may be adapted to transmit the same test signal or same potential, such as a reference potential like ground. According to another example, if the compliance tests of the chips 50A and 50B require only an odd number of test pads 55, one of the pads may be a dummy test pad, that is, a test pad that is not connected.

As described in connection with FIGS. 4A and 4B, an area 57 (shaded in FIG. 5) of the chips 50A and 50B is reserved for mobile circuits. The area 57 is defined similarly to the area 47 of chips 40A and 40B in FIG. 4B. More particularly, the area 57 is the same shape and area as the recess 53 arranged on the opposite side of the recess 53 on the chip 50A or 50B. More particularly, the area 57 may be aligned with the recess 53 on the other chip 50B or 50A in the group 50, as shown in FIG. 5.

Furthermore, the test pads 55 embedded in the chip 50A or 50B, respectively, are electrically connected to each of the chips of the group 50, and in particular to the other chip, that is, the chip 50B or 50A, respectively, by buses 58. Each bus 58 comprises one or more conductive strips of a material that can be cut by the same cutting method as the plate on and in which the chips 50A and 50B are formed. According to one embodiment, if the plate cutting method is a plasma cutting method, the buses 58 may be made of polycrystalline silicon.

One advantage of this embodiment is that it makes it possible to economize on a laser cutting method for cutting the test pads 55 if their material is unsuitable for cutting by a particle beam cutting method, such as a plasma cutting method.

One example of a cutting method for individualizing the chips 50A and 50B may include the following sequential steps:
a laser cutting method that makes it possible to prepare to cut the plate on and into which the chips 50A and 50B are formed; and
a plasma cutting method that makes it possible to cut through said plate.

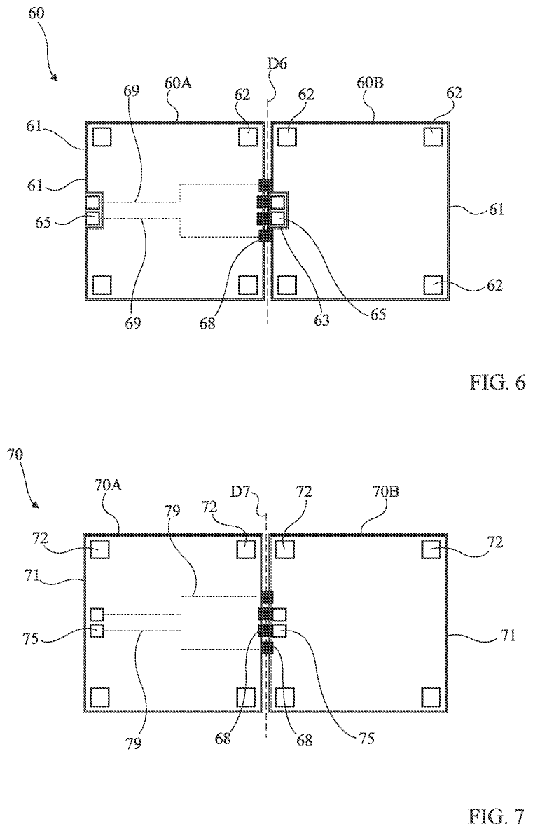

FIG. 6 is a schematic view from above of another embodiment of a finished group 60, comprising two chips 60A and 60B.

The group 60 and the chips 60A and 60B are similar to the group 50 and the chips 50A and 50B described in connection with FIGS. 4A and 4B. The elements common to the groups, 50 and 60, and the chips 50A and 50B and the chips 60A and 60B will not be described again in detail here. Only the differences between the groups 50 and 60, and the chips 50A and 50B and the chips 60A and 60B will be highlighted.

Thus, each chip 60A, 60B comprises one or more functional circuits surrounded by a seal ring 61 that defines the shape of the chip 60A, 60B, and four connection pads 62.

In addition, each group 60 thus comprises two adjacent chips 60A, 60B, between which test pads 65, identical to the test pads 32 described in connection with FIG. 3, are arranged. Like the group 50, the group 60 comprises an even number of test pads 65.

The group 60 overcomes one drawback of the group 50, in which the chips 50A and 50B are not the same shape, which can lead to problems when using the chips 50A and 50B. Indeed, positioning errors can be generated by the difference in shape of the chips 50A and 50B.

In the group 60, the recess 63 of the chip 60A or the recess 63 of the chip 60B are positioned on the same side of the chip 60A or 60B, such as the left side in FIG. 6. Thus, a first half of the test pads 65 is positioned on a first side of the chip 60A, such as the left side, and a second half of the test pads 65 is positioned on the same side of the chip 60B, such as the left side. The recesses 63 of the chips 60A and 60B are positioned at the same level on the side of the chips 60A and 60B.

To connect the test pads 65 to the chips 60A and 60B, each test pad 65 is connected to a bus 68, of the same type as the bus 58 described in connection with FIG. 5, passing through a cutting line D6 separating the chips 60A and 60B. More particularly, since the chip 60A is on the left side in FIG. 6 and the chip 60B is on the right side in FIG. 6, the test pads 65 embedded in the chip 60B are connected to the chip 60A directly by buses 68. The test pads 65 embedded in the chip 60A are connected to the chip 60B by conductive tracks 69 through the chip 60A and by buses 68. Even more specifically, each test pad 65 embedded in the chip 60A is connected to the chip 60B by a conductive track 69, which is itself connected to a bus 68.

One advantage of this embodiment is that the chips 60A and 60B have the same shape. To make the chips 60A and 60B even more similar, dummy conductive tracks can be formed in the chip not requiring conductive tracks 69, the chip 60B in the case of FIG. 6.

The person skilled in the art will know how to adapt this embodiment by placing the test pads on either side of the chips 60A and 60B.

FIG. 7 is a schematic view from above of another embodiment of a finite group 70 comprising two chips 70A and 70B.

The group 70, and the chips 70A and 70B are similar to the group 60, and the chips 60A and 60B described in connection with FIGS. 4A and 4B. The elements common to the groups 60 and 70, and the chips 60A and 60B and the chips 70A and 70B will not be described again in detail here. Only the differences between the groups 60 and 70, and the chips 60A and 60B and the chips 70A and 70B will be highlighted.

Each group 70 thus comprises two adjacent chips 70A and 70B and an even number of test pads 75. Each chip 70A, 70B includes one or more functional circuits surrounded by a seal ring 71 that defines the shape of the chip 70A, 70B, and four connection pads 72.

Unlike the embodiments of FIGS. 4A, 4B, 5 and 6, in the embodiment of FIG. 7, the test pads 75 are not positioned at the periphery of the chips 70A, 70B, that is, outside the seal ring, but inside the chips 70A, 70B. More particularly, the test pads 75 are arranged within the seal ring 71 of the chips 70A and 70B, but at a location substantially identical to the location of the test pads 65 described in connection with FIG. 6. Similarly, the test pads 75 are connected to the chips 70A or 70B, as the case may be, by the same conduction devices, that is, conductor tracks 79 and buses 78 identical to the conductor tracks 69 and buses 68 described in connection with FIG. 6. Only the buses 68 crossing the cutting line D7 separate the chips 70A and 70B.

Thus, the chips 70A and 70B, and thus their seal rings, are substantially rectangular or substantially square in shape and do not have any recesses at the test pads. One advantage of this embodiment is that the seal rings 71 of the chips 70A and 70B do not have a concave portion.

One advantage of this embodiment is that the chips 70A and 70B have a more compact shape and are easier to manufacture. Indeed, it is potentially more reliable to make a rectangular or square shaped seal ring without a recess.

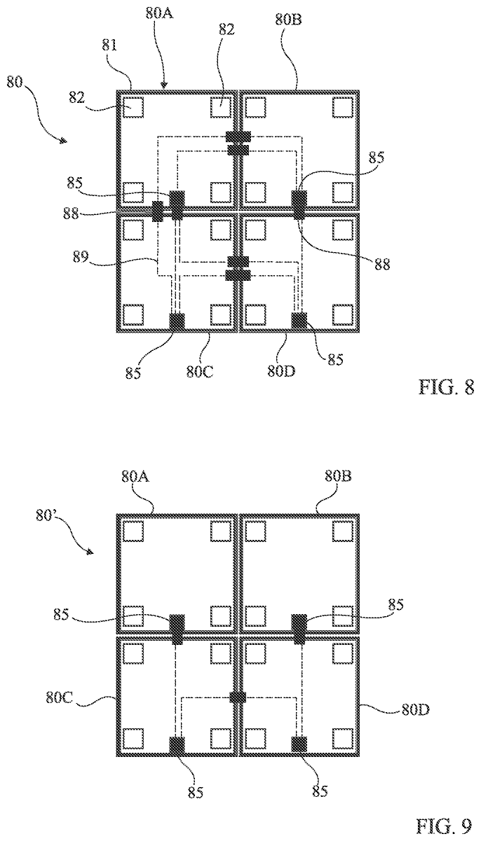

FIG. 8 is a schematic view from above of another embodiment of a finite group 80 showing a variant embodiment of the group 70 described in connection with FIG. 7.

Unlike the group 70, the group 80 comprises four integrated circuit chips 80A, 80B, 80C and 80D arranged in two rows and two columns. According to one example, in FIG. 8, the chips 80A and 80C form a first column, and the chips 80B and 80D form a second column. Further, a first row is formed by the chips 80A and 80B, and a second row is formed by the chips 80C and 80D.

The chips 80A, 80B, 80C, and 80D are similar to the chips 70A and 70B, Each chip 80A, 80B, 80C, and 80D includes one or more functional circuits surrounded by a seal ring 81 that defines the shape of the chip 80A, 80B, 80C, and 80D, and four connection pads 82.

In addition, as with the group 70, the group 80 uses four test pads 85 to implement the compliance test methods for chips 80A through 80D. As a result, unlike the chips 70A and 70B, the chips 80A through 80D each comprise a single test pad 85 positioned within their seal ring 81.

In the embodiment shown in FIG. 8, the four test pads 85 are adapted to receive or transmit different signals and potentials. The group 80 comprises a network of conductive tracks 89 and buses 88 for connecting all the test pads 85 to all the chips 80A through 80D.

In the example shown in FIG. 8, an example of such a network is illustrated. The person skilled in the art will know how to provide other networks making it possible to connect each test pad 85 to all the chips, 80A through 80D.

FIG. 9 is a schematic view from above of a variant embodiment 80′ of the finite group 80 described in connection with FIG. 8, in which two test pads 85 provide the same potential, a reference potential, for example, such as ground.

In the example of FIG. 9, the test pads of the chips 80A and 80B are both provided with the same potential, a reference potential, for example, such as ground. The network of conductive tracks 89 and buses 88 is thus simplified as compared to that of the group 80.

Various embodiments and variants have been described. Those skilled in the art will understand that certain features of these embodiments can be combined and other variants will readily occur to those skilled in the art. In particular, the person skilled in the art will know how to adapt the described embodiments to more than two or four chips in a group, and to a different number of test pads per chip group.

Finally, the practical implementation of the embodiments and variants described herein is within the capabilities of those skilled in the art based on the functional description provided hereinabove.

1. An electronic chip, comprising:
a seal ring whose shape is contained within a rectangle having a width equal to a maximum width of said electronic chip and a length equal to a maximum length of said electronic chip; and
at least one test pad arranged, at least partially, at a location in said rectangle;
wherein said test pad is shared with at least one other electronic chip.

2. The electronic chip according to claim 1, wherein said test pad is arranged outside of said seal ring.

3. The electronic chip according to claim 2, wherein said seal ring has a recess of substantially rectangular shape at the location of said at least one test pad, said at least one test pad being embedded in said recess.

4. The electronic chip according to claim 3, comprising at least one circuit arranged in an area of same size as the recess and arranged against a first side of the electronic chip, opposite a second side of the chip where said recess is formed, said at least one circuit being a circuit whose position in said electronic chip can be modified.

5. The electronic chip according to claim 2, wherein said recess is arranged on a cutting line that makes it possible to individualize said electronic chip at the end of its manufacturing method.

6. The electronic chip according to claim 2, wherein said test pad is positioned next to a cutting line that makes it possible to individualize said electronic chip at the end of its manufacturing method.

7. The electronic chip according to claim 1, wherein said test pad is arranged inside said seal ring, and said seal ring has the shape of said rectangle.

8. The electronic chip according to claim 1, wherein said test pad is shared with a group of electronic chips.

9. The electronic chip according to claim 1, wherein said test pad is connected to said at least one other electronic chip by a communication bus made of a non-metallic material.

10. The electronic chip according to claim 9, wherein said non-metallic material is polycrystalline silicon.

11. A method, comprising:
manufacturing a group of electronic chips, wherein each electronic chip includes a seal ring whose shape is contained within a rectangle having a width equal to a maximum width of said electronic chip and a length equal to a maximum length of said electronic chip, and at least one test pad arranged, at least partially, at a location in said rectangle;
wherein said test pad is shared by at least two adjacent electronic chips of the group of electronic chips; and
individualizing the electronic chips from the group of electronic chips using a particle beam cutting.

12. The method according to claim 11, wherein individualizing using particle beam cutting comprises performing a plasma cutting.

13. The method according to claim 11, wherein individualizing using particle beam cutting comprises performing a laser cutting.

14. The method according to claim 11, wherein adjacent electronic chips of the group of electronic chips are spaced apart from each other by a minimum spacing that is defined by a width of the cutting.

15. The method according to claim 14, wherein the minimum spacing is greater than or equal to 15 μm.

16. The method according to claim 11, wherein said test pad is arranged outside of said seal ring.

17. The method according to claim 16, further comprising forming a recess of substantially rectangular shape for said seal ring at the location of said at least one test pad, said at least one test pad being embedded in said recess.

18. The method according to claim 17, further comprising forming the recess arranged on a cutting line through which individualizing the electronic chips is made.

19. The method according to claim 16, wherein said test pad is positioned next to a cutting line through which individualizing the electronic chips is made.

20. The method according to claim 11, wherein said test pad is arranged inside said seal ring, and said seal ring has the shape of said rectangle.

21. The method according to claim 11, wherein said test pad is shared by said group of electronic chips.

22. The method according to claim 11, further comprising electrically connecting said test pad to at least one other electronic chip.
